(19) United States
(12) Patent Application Publication
(10) Pub. No.: US 2009/0160517 A1
(43) Pub. Date: Jun. 25, 2009

(54) FLIP-FLOP

(76) Inventor: Mei-Chao Yeh, Kaohsiung City (TW)

Correspondence Address: NORTH AMERICA INTELLECTUAL PROPERTY CORPORATION, P.O. BOX 506, MERRIFIELD, VA, 22116, US

(21) Appl. No.: 12/339,025

(22) Filed: Dec. 18, 2008

(30) Foreign Application Priority Data
Dec. 20, 2007 (TW) 096148892

(51) Int. Cl. H03K 3/00

(52) U.S. Cl. 327/212; 327/211

(57) ABSTRACT

An apparatus comprises a first stage, a second stage, and a switch circuit. The first stage and the second stage are coupled between a first reference voltage and a second reference voltage. The first stage has a first input end for receiving an input signal and a first output end for outputting a first output signal. The second stage has a second input end for receiving the first output signal from the first output end of the first stage and a second output end for outputting a second output signal. The switch circuit is coupled between the second stage and at least one of the first reference voltage and the second reference voltage for receiving a power control signal and for turning on or turning off according to the power control signal such that the current leakage of the second stage is reduced.

### BACKGROUND OF THE INVENTION

1. Field of the Invention

The present invention relates to a flip-flop, and more particularly, to a flip-flop for reducing the number of transistors by using a clock signal and an inverted clock signal.

2. Description of the Prior Art

A flip-flop is a circuit capable of storing one bit data. Due to the flip-flop usually being applied to a basic architecture block of a counter, a resistor, or other timing control logic circuit, it is also called a bi-stable multi-vibrator. Presently, a variety of flip-flops exist, such as RS-type flip-flops, D-type flip-flops, T-type flip-flops, and J-K flip-flops, and most of them can be built from different kinds of logic gates. These logic gates can be built from transistors implemented by NMOS, PMOS, CMOS, or TTL.

In the prior art, the conventional D-type flip-flop is implemented by adopting true signal phase clock (TSPC) technology. This kind of D-type flip-flop is composed of nine transistors and two inverters. It samples data when the clock signal CLK is logic “0” and transmits data to the output end when the clock signal CLK is logic “1”. However, this conventional D-type flip-flop requires at least four stages of circuits, which requires a delay time of at least two or three inverters. In addition, if the whole circuit is powered off, both the last stage of the circuit and its output end are floating. Hence, it cannot be determined whether their logic level is logic “0” or “1”, which can result in current leakage.

Although an improved D-type flip-flop architecture has been proposed to reduce the number of transistors in the related patents in this field, this similarly adopts the TSPC technology to complete the improved D-type flip-flop. Thus the delay time for transmitting data from the input end to the output end of the flip-flop still cannot be shortened and current leakage cannot be prevented when powering off the circuit.

### SUMMARY OF THE INVENTION

It is one of the objectives of the present invention to provide a flip-flop to solve the abovementioned problems.

It is one of the objectives of the present invention to provide a flip-flop for reducing the number of transistors to save area and power consumption, and for reducing delay time of the flip-flop to improve the operational frequency of the flip-flop.

According to an exemplary embodiment of the present invention, an apparatus is provided. The apparatus comprises a first stage, a second stage, and a switch circuit. The first stage and the second stage are coupled between a first reference voltage and a second reference voltage. The first stage has a first input end for receiving an input signal and a first output end for outputting a first output signal. The second stage has a second input end for receiving the first output signal from the first output end of the first stage and a second output end for outputting a second output signal. The switch circuit is coupled between the second stage and at least one of the first reference voltage and the second reference voltage for receiving a power control signal and for turning on or turning off according to the power control signal such that the current leakage of the second stage is reduced.

According to another exemplary embodiment of the present invention, a method for reducing a current leakage is provided. The method comprises the steps of providing a first stage and a second stage, the first stage and the second stage coupled between a first reference voltage and a second reference voltage, wherein the first stage comprises a first input end for receiving an input signal and a first output end for outputting a first output signal, and the second stage comprises a second input end for receiving the first output signal and a second output end for outputting a second output signal; and turning on or turning off at least one of the first and second stages according to a power control signal such that the current leakage is reduced.

According to another exemplary embodiment of the present invention, a flip-flop is provided. The flip-flop comprises a first stage and a second stage. The first stage is coupled between a first reference voltage and a second reference voltage for receiving an input signal and for outputting a first output signal. The second stage is coupled between the first reference voltage and the second reference voltage for receiving the first output signal and for outputting a second output signal. Each of the first stage and the second stage comprises a first transistor, a second transistor, a third transistor, and a fourth transistor. The first transistor comprises a first control end. The second transistor comprises a second control end for receiving a clock signal. The third transistor comprises a third control end for receiving an inverted clock signal. The fourth transistor comprises a fourth control end coupled to the first control end, wherein the first transistor, the second transistor, the third transistor, and the fourth transistor are coupled to each other in cascode.

These and other objectives of the present invention will no doubt become obvious to those of ordinary skill in the art.

### BRIEF DESCRIPTION OF THE DRAWINGS

FIG. 1 is a diagram of a flip-flop according to a first embodiment of the present invention.

FIG. 2 is a diagram of a flip-flop according to a second embodiment of the present invention.

FIG. 3 is a diagram of a flip-flop according to a third embodiment of the present invention.

FIG. 4 is a diagram of a flip-flop according to a fourth embodiment of the present invention.

FIG. 5 is a diagram of a flip-flop according to a fifth embodiment of the present invention.

FIG. 6 is a diagram showing an example of applying the flip-flop according to an embodiment of the present invention.

### DETAILED DESCRIPTION

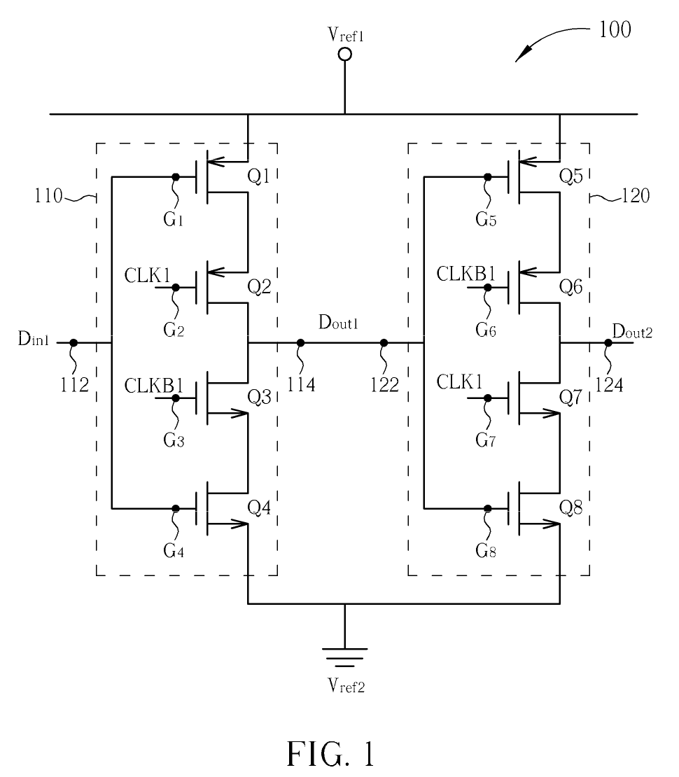

Please refer to FIG. 1. FIG. 1 is a diagram of a flip-flop 100 according to a first embodiment of the present invention. The flip-flop 100 comprises a first stage 110 and a second stage 120. The first stage 110 is coupled between a first reference voltage Vref1 and a second reference voltage Vref2. In this embodiment, the first reference voltage Vref1 is at a high voltage level and the second reference voltage Vref2 is at a low voltage level, merely as an example for describing features of the present invention. The first stage 110 comprises an input end 112 for receiving an input signal Din1 and an output end 114 for outputting a first output signal Dout1. The second stage 120 is coupled between the first reference voltage Vref1 and the second reference voltage Vref2. The second stage 120 comprises an input end 122 coupled to the output end 114 of the first stage 110 for receiving the first output signal Dout1 and an output end 124 for outputting a second output signal Dout2. In this embodiment, the flip-flop is a D-type flip-flop.

Please keep referring to FIG. 1. The first stage 110 comprises a first transistor Q1, a second transistor Q2, a third transistor Q3, and a fourth transistor Q4. The first transistor Q1 has a control end G1 for receiving the input signal Din1. The second transistor Q2 has a control end G2 for receiving a clock signal CLK1. The third transistor Q3 has a control end G3 for receiving an inverted clock signal CLKB1, which is out of phase to the clock signal CLK1. The fourth transistor Q4 has a control end G4 for receiving the input signal Din1. The transistors Q1-Q4 are cascoded to each other, i.e., cascoded between the first reference voltage Vref1 and the second reference voltage Vref2. In this embodiment, the second transistor Q2 is coupled between the first transistor Q1 and the third transistor Q3 in cascode, and the third transistor Q3 is coupled between the second transistor Q2 and the fourth transistor Q4 in cascode. The second stage 120 comprises a fifth transistor Q5, a sixth transistor Q6, a seventh transistor Q7, and an eighth transistor Q8. The fifth transistor Q5 has a control end G5 for receiving the first output signal Dout1. The sixth transistor Q6 has a control end G6 for receiving the inverted clock signal CLKB1. The seventh transistor Q7 has a control end G7 for receiving the clock signal CLK1. The eighth transistor Q8 has a control end G8 for receiving the first output signal Dout1. The transistors Q5-Q8 are cascoded to each other, i.e., cascoded between the first reference voltage Vref1 and the second reference voltage Vref2. In this embodiment, the sixth transistor Q6 is coupled between the fifth transistor Q5 and the seventh transistor Q7 in cascode, and the seventh transistor Q7 is coupled between the sixth transistor Q6 and the eighth transistor Q8 in cascode.

In this embodiment, each of the first transistor Q1, the second transistor Q2, the fifth transistor Q5, and the sixth transistor Q6 is a P-type transistor. Each of the third transistor Q3, the fourth transistor Q4, the seventh transistor Q7, and the eighth transistor Q8 is an N-type transistor. But those skilled in the art should know that this should not limit the present invention. Approximate modifications and alterations to the circuit shown in FIG. 1 may be made without departing from the spirit of the present invention, which also belong to the scope of the present invention.

In the following, descriptions of how each element and each signal of the flip-flop signal 100 shown in FIG. 1 operates are divided into several conditions. In the first condition, when the input signal Din1 is logic “1” and the clock signal CLK1 is logic “0”, the third transistor Q3 and the fourth transistor Q4 are turned on. At this time, the first output signal Dout1 outputted from the output end 114 of the first stage 110 is logic “0”. When the clock signal CLK1 is transformed from “0” to “1”, the inverted signal CLKB1 is transformed from “1” to “0”, which needs a delay time of an inverter. At this time, the fifth transistor Q5 and the sixth transistor Q6 are turned on, and the second output signal Dout2 outputted from the output end 124 of the second stage 120 is logic “1”. In the second condition, when the input signal Din1 is logic “0” and the clock signal CLK1 is logic “0”, the first transistor Q1 and the second transistor Q2 are turned on. At this time, the first output signal Dout1 outputted from the output end 114 of the first stage 110 is logic “1”. When the clock signal CLK1 is transformed from “0” to “1”, the seventh transistor Q7 and the eighth transistor Q8 are turned on. At this time, the second output signal Dout2 outputted from the output end 124 of the second stage 120 is logic “0”. Under the first condition, it takes a delay time of two inverters to transmit data from the input end to the output end of the flip-flop 100. Under the second condition, it only takes the delay time of one inverter to transmit data from the input end to the output end of the flip-flop 100. Therefore, the flip-flop 100 disclosed in the present invention can effectively reduce the delay time for transmitting data from the input end to the output end, for further improving the operating frequency of the flip-flop.

Please note that the abovementioned flip-flop 100 comprises two stages of circuits (i.e., the first stage 110 and the second stage 120) in total, which can replace the conventional flip-flop, which uses an architecture needing four stages of circuits. Therefore, not only can the number of transistors be decreased but also the delay time for transmitting data from the input end to the output end can be reduced. If the flip-flop disclosed in the present invention is applied to a circuit architecture needing multiple cascaded flip-flops, its effect is even more noticeable, which should also belong to the scope of the present invention.

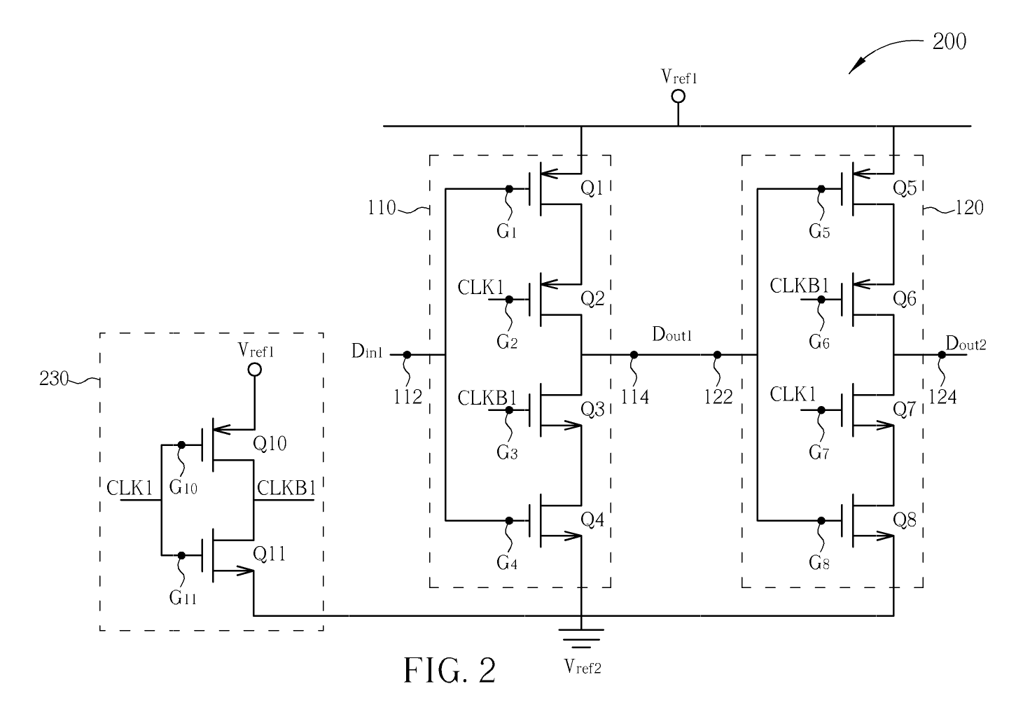

The abovementioned clock signal CLK1 and the inverted clock signal CLKB1 can be directly implemented by a pair of differential signals, or a corresponding inverted clock signal can be generated by an inverter according to a single clock signal. Please refer to FIG. 2. FIG. 2 is a diagram of a flip-flop 200 according to a second embodiment of the present invention. The flip-flop 200 is similar to the flip-flop 100 shown in FIG. 1, the difference between them being that the flip-flop 200 further comprises an inverter 230 coupled between the first reference voltage Vref1 and the second reference voltage V_{ref2}. The inverter 230 comprises a tenth transistor Q10 and a eleventh transistor Q11. A control end G₁₀ of the tenth transistor Q10 is coupled to a control end G11 of the eleventh transistor Q11 for receiving the clock signal CLK1. The inverter 230 is used for generating the inverted clock signal CLKB1 according to the clock signal CLK1, which is provided for the use of the transistors of the first stage 110 and the second stage 120. In this embodiment, the tenth transistor Q10 is a P-type transistor and the eleventh transistor Q11 is an N-type transistor.

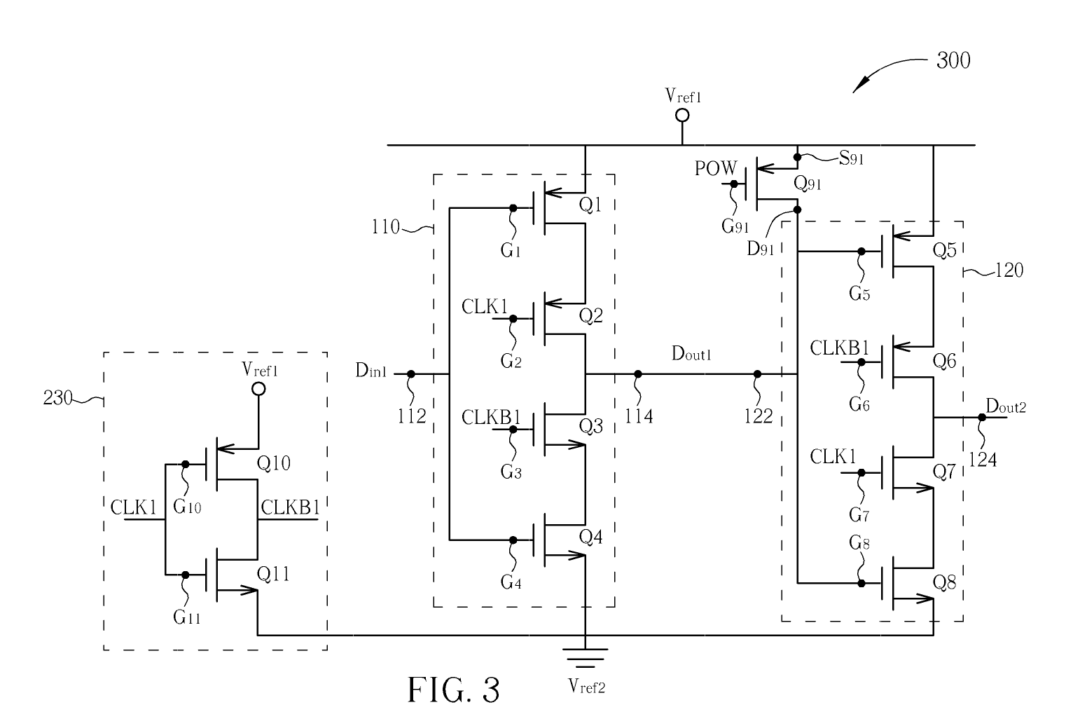

In order to solve the current leakage problem resulted from turning off the circuit, the flip-flop 200 above can be improved. Please refer to FIG. 3. FIG. 3 is a diagram of a flip-flop 300 according to a third embodiment of the present invention. The flip-flop 300 is similar to the flip-flop 200 shown in FIG. 2, the difference between them being that the flip-flop 300 further comprises a ninth transistor Q91. The ninth transistor Q91 has a control end G91 for receiving a power control signal POW, a first end S91 coupled to the first reference voltage Vref1, and a second end D91 coupled to the control end G5 of the fifth transistor Q5. When the flip-flop 300 is powered off, the power control signal POW is logic “0” and the ninth transistor Q91 is turned on. In other words, the ninth transistor Q91 is viewed as a switch circuit to be turned on or turned off the according to the power control signal POW such that the current leakage of the second stage is reduced. The control end G5 of the fifth transistor Q5 is logic “1”, and thus the fifth transistor Q5 is turned off. Hence, the second stage 120 cannot provide a current path flowing through the first reference voltage Vref1 to the second reference voltage Vref2 to prevent current leakage.

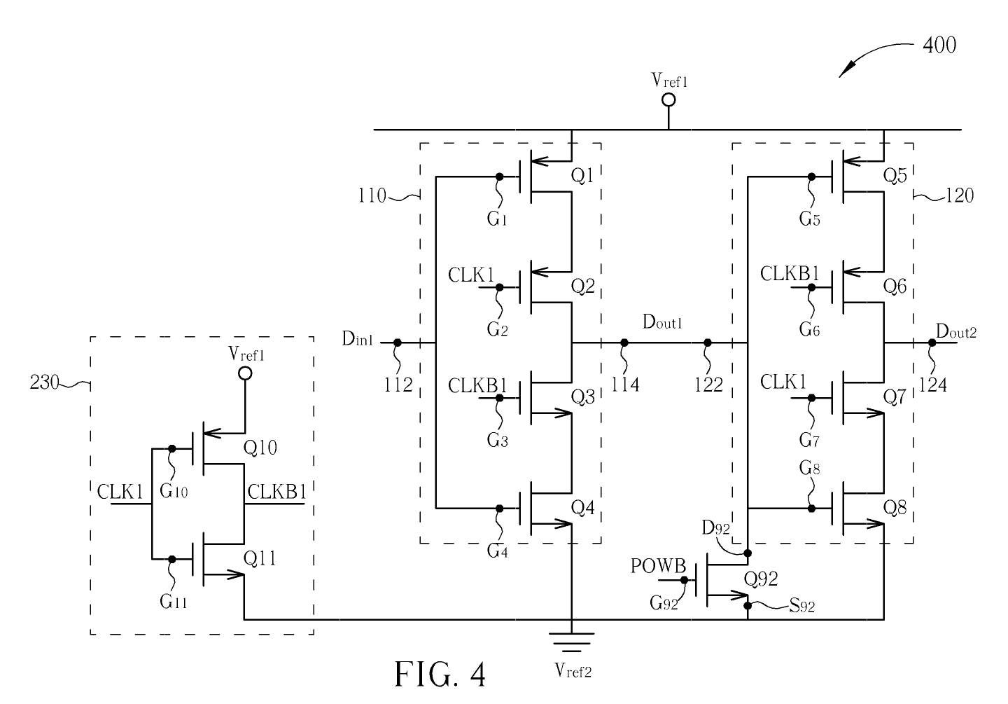

The abovementioned ninth transistor Q91 is implemented by a P-type transistor, but those skilled in the art should know that this should not be considered as a limitation of the present invention. Please refer to FIG. 4. FIG. 4 is a diagram of a flip-flop 400 according to a fourth embodiment of the present invention. The flip-flop 400 is similar to the flip-flop 300 shown in FIG. 3, the difference between them being that a ninth transistor Q92 included in the flip-flop 400 is an N-type transistor. The ninth transistor Q92 has a control end G92 for receiving an inverted power control signal POWB, a first end S92 coupled to the second reference voltage Vref2, and a second end D92 coupled to the control end G8 of the eighth transistor Q8. When the flip-flop 400 is powered off, the inverted power control signal POWB is logic “1” and the ninth transistor Q92 is turned on. The control end G8 of the eighth transistor Q8 is logic “0”, and thus the eighth transistor Q8 is turned off. Hence, the second stage 120 cannot provide a current path flowing through the first reference voltage Vref1 to the second reference voltage Vref2, preventing current leakage. Please note that the abovementioned power control signal POW and the inverted power control signal POWB are mutually complementary signals. This mechanism for preventing current leakage is applied when the circuit is powered off, and the clock signal CLK1 is logic “1” at this time.

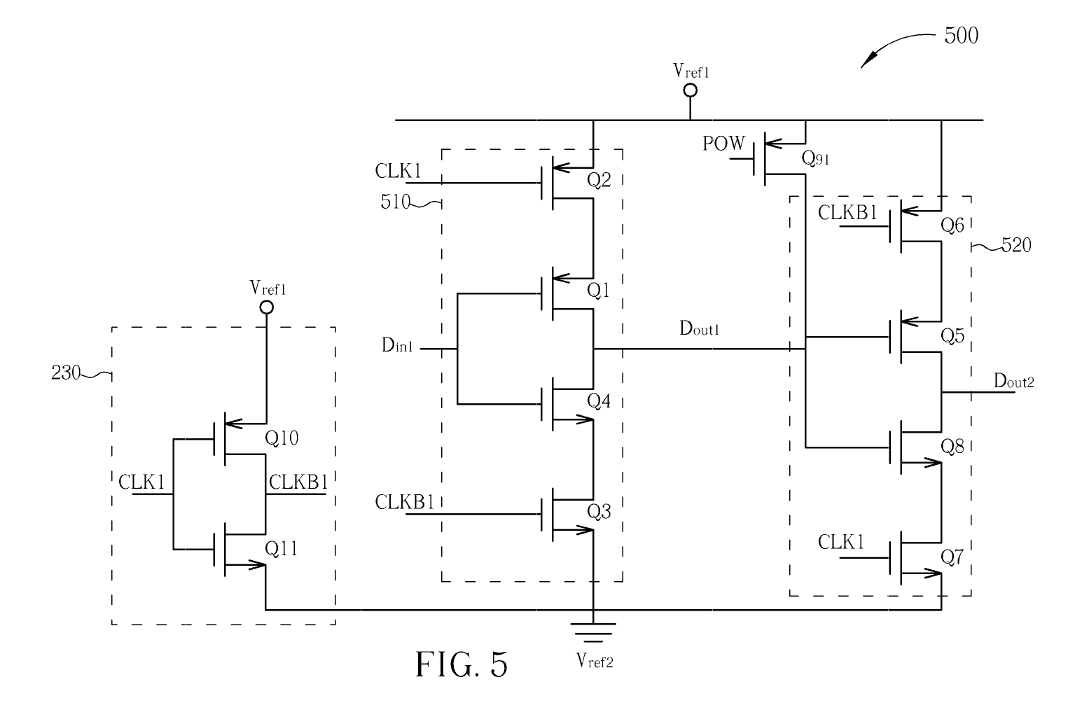

Please refer to FIG. 5. FIG. 5 is a diagram of a flip-flop 500 according to a fifth embodiment of the present invention. The flip-flop 500 is similar to the flip-flop 300 shown in FIG. 3, the difference between them being that the manner of connection of each transistor included in a first stage 510 and a second stage 520 of the flip-flop 500 is different from that included in the first stage 110 and the second stage 120 of the flip-flop 300. As shown in FIG. 5, the second transistor Q2, the first transistor Q1, the fourth transistor Q4, and the third transistor Q3 are cascoded to each other, wherein the first transistor Q1 is coupled between the second transistor Q2 and the fourth transistor Q4 in cascode, and the fourth transistor Q4 is coupled between the first transistor Q1 and the third transistor Q3 in cascode. In addition, the sixth transistor Q6, the fifth transistor Q5, the eighth transistor Q8, and the seventh transistor Q7 are cascoded to each other, wherein the fifth transistor Q5 is coupled between the sixth transistor Q6 and the eighth transistor Q8 in cascode, and the eighth transistor Q8 is coupled between the fifth transistor Q5 and the seventh transistor Q7 in cascode. Those skilled in the art should observe that various modifications and alterations of the connection manner of each transistor included by the first stages 110 and 510 and the second stages 120 and 520 may be made without departing from the spirit of the present invention.

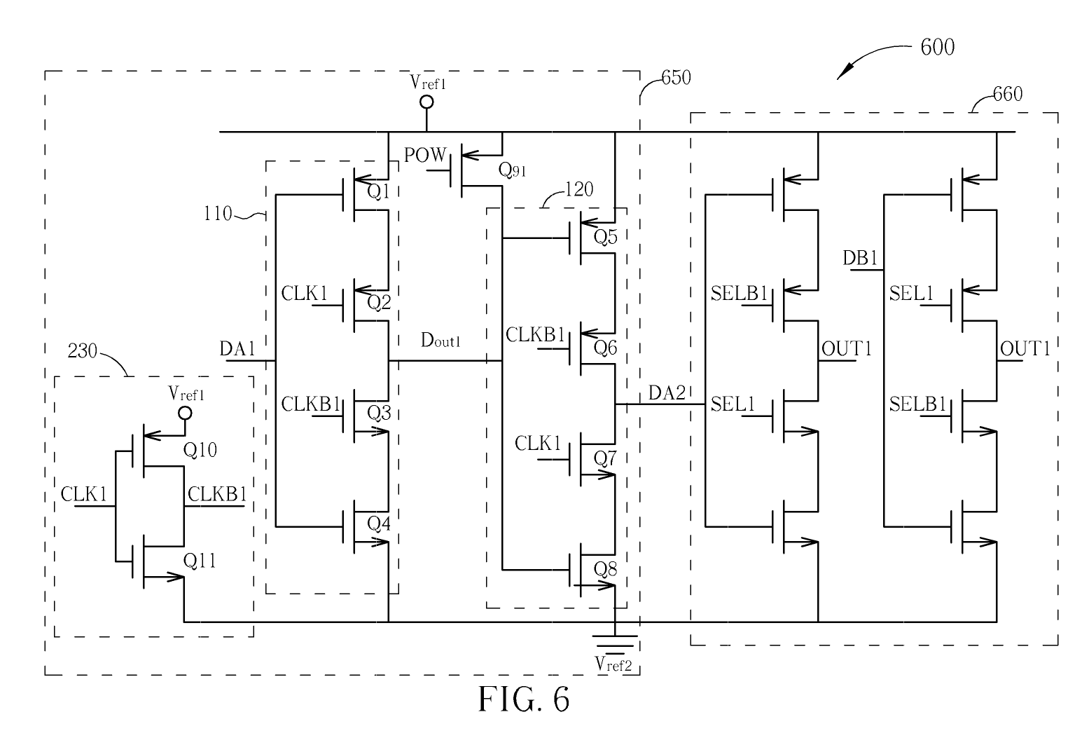

Please refer to FIG. 6. FIG. 6 is a diagram showing an example of applying the flip-flop according to an embodiment of the present invention. In this embodiment, an application circuit 600 comprises a flip-flop 650 and a multiplexer 660, wherein the flip-flop 650 is implemented by the flip-flop 300 shown in FIG. 3. The flip-flop 650 receives an input signal DA1 to generate an output signal DA2. However, those skilled in the art should know that the flip-flop 650 can be implemented by any one of the flip-flops 100-500, and should not be considered as a limitation of the present invention. The multiplexer 660, coupled between the first reference voltage Vref1 and the second reference voltage Vref2, is cascaded beyond the flip-flop 650 for receiving the output signal DA2 from the flip-flop 650 together with an input signal DB1 and for selecting one of the output signal DA2 and the input signal DB1 to output (i.e. being a data output signal OUT1) according to a selecting signal SEL1 and an inverted selecting signal SELB1.

Please note that the flip-flop disclosed in the present invention is not limited to the application circuit 600 having the multiplexer, and can be applied to other types of application circuits. Through using the flip-flop disclosed in the present invention in conjunction with other logic circuits, the delay time of the whole application circuit can be reduced to further improve the operating speed of the application circuit.

The abovementioned embodiments are presented merely for describing the present invention, and in no way should be considered to be limitations of the scope of the present invention. The above-mentioned flip-flops 100-500 can be D-type flip-flops, but are not limited to these only. That is, a flip-flop architecture applying the features disclosed in the present invention should also belong to the scope of the present invention. The abovementioned clock signal CLK1 and the inverted clock signal CLKB1 can be directly generated by a pair of differential signals, or a corresponding inverted clock signal can be generated by an inverter according to a single clock signal. But those skilled in the art should know that this should not be considered as a limitation of the present invention. In addition, the ninth transistor Q91 or Q92 can be added into the flip-flop to avoid current leakage. Please note that each of the transistors (Q1-Q8, Q91, Q91, Q10 and Q11) mentioned above can also be implemented by a P-type transistor or an N-type transistor, but this is not a limitation of the present invention. The connection manner of each transistor included by the first stage and the second stage is not a fixed type. Those skilled in the art should observe that various modifications and alterations of the connection manner of each transistor included by the first stages 110 and 510 and the second stages 120 and 520 may be made without departing from the spirit of the present invention. Furthermore, the flip-flop disclosed in the present invention is not limited to the application circuit 600 having the multiplexer, and can be applied to other types of application circuits.

In summary, the present invention provides a flip-flop. Through the technology of the clock signal CLK1 and the inverted clock signal CLKB1, the flip-flop circuit architecture can be simplified into two stages (i.e., the first stage 110 or 510 and the second stage 120 or 520). Therefore, not only can the number of transistors be decreased but also the delay time for transmitting data from the input end to the output end can be reduced to one or two inverters, which further improves the operating frequency of the flip-flop. If the flip-flop disclosed in the present invention is applied to a circuit architecture needing multiple cascaded flip-flops, its effect is even more noticeable. In addition, through adding the ninth transistor Q91 or Q92 into the flip-flop, the flip-flop can be further improved to prevent current leakage.

Those skilled in the art will readily observe that numerous modifications and alterations of the device and method may be made while retaining the teachings of the invention.

What is claimed is:

1. An apparatus, comprising:
a first stage, coupled between a first reference voltage and a second reference voltage, having a first input end for receiving an input signal and a first output end for outputting a first output signal;
a second stage, coupled between the first reference voltage and the second reference voltage, having a second input end for receiving the first output signal from the first output end of the first stage and a second output end for outputting a second output signal; and
a switch circuit, coupled between the second stage and at least one of the first reference voltage and the second reference voltage, for receiving a power control signal, and for turning on or turning off according to the power control signal such that the current leakage of the second stage is reduced.

2. The apparatus of claim 1, wherein the first stage comprises:
a first transistor, comprising a first control end for receiving the input signal;
a second transistor, comprising a second control end for receiving a clock signal;
a third transistor, comprising a third control end for receiving an inverted clock signal; and
a fourth transistor, comprising a fourth control end for receiving the input signal, wherein the first transistor, the second transistor, the third transistor, and the fourth transistor are coupled to each other in cascode.

3. The apparatus of claim 1, wherein the switch circuit comprises a transistor.

4. The apparatus of claim 1, wherein each of the first transistor and the second transistor is a P-type transistor.

5. The apparatus of claim 1, wherein each of the third transistor and the fourth transistor is an N-type transistor.

6. The apparatus of claim 1, wherein the second transistor is coupled between the first transistor and the third transistor in cascode, and the third transistor is coupled between the second transistor and the fourth transistor in cascode.

7. The apparatus of claim 1, wherein the first transistor is coupled between the second transistor and the fourth transistor in cascode, and the fourth transistor is coupled between the first transistor and the third transistor in cascode.

8. A method for reducing a current leakage, comprising:
providing a first stage and a second stage, the first stage and the second stage coupled between a first reference voltage and a second reference voltage, wherein the first stage comprises a first input end for receiving an input signal and a first output end for outputting a first output signal, and the second stage comprises a second input end for receiving the first output signal and a second output end for outputting a second output signal; and
turning on or turning off at least one of the first and second stages according to a power control signal such that the current leakage is reduced.

9. A flip-flop, comprising:
a first stage, coupled between a first reference voltage and a second reference voltage, for receiving an input signal and for outputting a first output signal; and
a second stage, coupled between the first reference voltage and the second reference voltage, for receiving the first output signal and for outputting a second output signal;
wherein each of the first stage and the second stage comprises:
a first transistor, comprising a first control end;
a second transistor, comprising a second control end for receiving a clock signal;
a third transistor, comprising a third control end for receiving an inverted clock signal; and
a fourth transistor, comprising a fourth control end coupled to the first control end, wherein the first transistor, the second transistor, the third transistor, and the fourth transistor are coupled to each other in cascode.

10. The flip-flop of claim 9, wherein each of the first transistor and the second transistor is a P-type transistor.

11. The flip-flop of claim 10, wherein each of the third transistor and the fourth transistor is an N-type transistor.

12. The flip-flop of claim 9, wherein the second transistor is coupled between the first transistor and the third transistor in cascode, and the third transistor is coupled between the second transistor and the fourth transistor in cascode.

13. The flip-flop of claim 9, wherein the first transistor is coupled between the second transistor and the fourth transistor in cascode, and the fourth transistor is coupled between the first transistor and the third transistor in cascode.

14. The flip-flop of claim 9, further comprising:
a switch circuit, coupled between the second stage and at least one of the first reference voltage and the second reference voltage, for receiving a power control signal, and for turning on or turning off according to the power control signal such that the current leakage of the second stage is reduced.

15. The flip-flop of claim 9, wherein an output end of the second stage is directly cascaded to a back-end circuit, and the back-end circuit is coupled between the first reference voltage and the second reference voltage.

16. The flip-flop of claim 15, wherein the back-end circuit is a multiplexer.
